(19) United States
(12) Patent Application Publication
(10) Pub. No.: US 2024/0164259 A1
(43) Pub. Date: May 23, 2024

(54) DEVICES, SYSTEMS, AND METHODS FOR PREDICTING THE GROWTH OF URBAN LANDSCAPE TREES

(71) Applicant: Nanjing Normal University, Nanjing (CN)

(72) Inventors: Min CHEN, Nanjing (CN); Jin WANG, Nanjing (CN); Teng ZHONG, Nanjing (CN); Songshan YUE, Nanjing (CN); Yuanqing HE, Nanjing (CN); Yongning WEN, Nanjing (CN); Guonian LV, Nanjing (CN)

(21) Appl. No.: 18/055,083

(22) Filed: Nov. 14, 2022

(51) Int. Cl. A01G 7/00; A01B 79/00; A01B 79/02; G01W 1/10

(52) U.S. Cl. CPC A01G 7/00; A01B 79/005; A01B 79/02; G01W 1/10; G06F 30/20

(57) ABSTRACT

The subject invention pertains to systems and methods for cost effective evaluation of the suitability of tree growth in a planting area before planting. Factors considered include whether the water and heat conditions of the area to be planted are suitable for the growth and development of the trees to be cultivated and how long the nutrient content in the soil can support the growth of the tree. The invention provides a “plug-and-play” urban landscape tree growth predictor. By inserting a “plunger” with a specialized sensor into the area to be planted, the instrument can automatically capture environmental data to drive the tree growth model, thus quickly simulating the tree's future growth. Through this method, the future growth trend of trees can be predicted and analyzed before planting to reduce the growth risk after planting.

### BACKGROUND OF THE INVENTION

Urban landscape tree planning is one of the important ways to improve the urban living environment and purify urban air. In urban planning, many landscape trees, such as camphor, maple, need to be planted. Different species of trees have different requirements for their growth environment. Trees planted in unsuitable environments have a low survival rate. And for some rare species, a lower survival rate will cause a certain loss in manpower, material, and financial resources. Due to the dynamics and complexity of the urban environment, the planted tree seedlings, especially some rare species, can die for lack of adapting to their living environment, thus causing certain economic losses. Urban planners can advance the planting plan to reduce tree mortality and unnecessary economic losses if they can predict the future growth of trees in the planted area before planting.

At present, there are a lot of research results about urban landscape tree planting: for example, choosing suitable landscape tree species for planting according to the environmental conditions of specific areas, such as planting landscape tree species with high cold-resistant in northern cities and planting landscape tree species that can effectively absorb noise and dust in transportation hubs (Zhao Xinya, 2020; Wang Shengxiang, 2020). Based on the geographical location, temperature, sunshine, rainfall, and soil texture type of the planting area, a comprehensive evaluation system was established to evaluate the growth suitability of tree species from the indexes of soil adaptability, drought resistance, cold resistance, growth type, life span and maintenance frequency (Ye Yiyun, 2020). Based on the expert experience method, the evaluation factors such as temperature, soil texture, organic matter, rainfall, sunshine, slope and aspect were selected to evaluate the growth suitability of trees (Peng Buzhuo et al., 1994; Zhang Hongqi, 1998; Ekanayake, et al, 2003; AbdelRahman, et al., 2016). A sensor device is used to monitor the growth of trees in real-time. If necessary, manual intervention is carried out to eliminate the survival risk of trees and improve their survival rate (WO2001087044A1, 2001; CN202890031U, 2013; CN111578906A, 2020). In summary, the evaluation method of landscape tree growth suitability based on prior knowledge lacks a scientific basis and cannot take into account the dynamic change of an urban environment, so its accuracy is low. Using sensors to monitor the growth of trees in real-time is tedious, requires deploying a large number of sensor devices, and takes a long period of time and economic cost.

### BRIEF SUMMARY OF THE INVENTION

Embodiments of the subject invention can provide systems and methods for the evaluation of the suitability of tree growth in a planning area before planting at an advantageously reduced cost. For example, whether the water and heat conditions of the area to be planted are suitable for the growth and development of the trees to be cultivated and how long the nutrient content in the soil can support the growth of a specified tree. The invention applies for designing a “plug-and-play” urban landscape tree growth predictor. By inserting a plunger with a specialized sensor into the area to be planted, certain embodiments can automatically capture environmental data to drive a tree growth model, thus quickly simulating a tree's future growth. Through this method, the future growth trend of trees can be predicted and analyzed before planting to reduce the growth risk after planting.

Embodiments can provide a plug-and-play urban landscape tree growth predictor that can evaluate the growth suitability of the area to be planted before planting, thus forecasting a future growth situation to provide decision support for planners. For example, landscape trees in the test area are healthy after one year, sub-healthy after two years and unhealthy after three years. Embodiments of the subject invention can combine software and hardware such that various environmental data of the area to be planted for landscape trees are collected by various sensor devices (e.g., hardware) to drive a tree growth model (e.g., software) to simulate the growth process of trees, and then analyze the simulation results to predict the future growth of the trees. Planners can make improved planting planning decisions based on the prediction. In certain embodiments, the environmental data of the area to be planted can include air temperature, humidity, rainfall, sun exposure, soil moisture, soil type, soil nutrient content, etc. There can be two main sources of this data: (1) Acquiring by commercial data acquisition sensors, such as temperature sensors, soil moisture sensors, and soil salt sensors; (2) Obtaining historical data of the planning area through network sensors, such as land use type data in the planning area, monthly average rainfall data, and monthly average temperature data, etc. In certain embodiments the tree growth model can be an algorithm or computer program used to describe the growth of the landscape tree. By inputting the environmental data of the planting area, the model can be driven to simulate the future growth of trees to assist decision-making.

### BRIEF DESCRIPTION OF THE DRAWINGS

FIG. 1 schematically illustrates an overall framework in accordance with one embodiment of the invention and comprising a multi-source data collector, a heterogeneous data adapter, a simulation resource center, a tree growth simulator, and a simulation results display device.

FIG. 2 schematically illustrates a simulation resource center comprising model resources and data resources in accordance with one embodiment of the invention.

FIG. 3 schematically illustrates a heterogeneous data adapter comprising a data description interface, a data mapping interface, and a data refactoring interface in accordance with one embodiment of the invention.

FIG. 4 graphically and schematically illustrates a data acquisition inserted link device in accordance with one embodiment of the invention and shows many of the elements of FIG. 1 with a simplified physical form overlayed by schematic representations of selected connections and relationships between elements.

FIG. 5 schematically illustrates a model simulation module comprising five sub-modules: respiration sub-module, dry matter production sub-module, dry matter allocation sub-module, leaf area calculation sub-module, and photosynthesis sub-module, as well as selected input data and interactions between sub-modules, in accordance with one embodiment of the invention.

FIG. 6 schematically illustrates a working process of an urban landscape tree growth predictor, comprising steps of tree species information collection, environmental data collection, data standardization processing, model invocation, and analysis of simulation results in accordance with one embodiment of the invention. Selected input resources and input data are also shown.

FIG. 7 schematically illustrates data visualization results based on model simulation process data (e.g., tree height, tree stem, tree crown, etc.) that can be displayed in the tree growth process visualization simulation device (e.g., on the interface of the host computer display) in accordance with one embodiment of the invention.

### DETAILED DISCLOSURE OF THE INVENTION

Embodiments of the subject invention can provide devices and methods for evaluating the suitability of tree growth, that can adopt a design concept of “combining virtual and real,” and combine the tree growth model (e.g., in software) with a commercial sensor device (e.g., in hardware). Using a plug-and-play method, embodiments can quickly collect certain environmental data of the planning area, and then drive the tree growth model to simulate and predict the future growth of trees. On the one hand, embodiments can be connected with a known tree growth model for tree growth prediction, and have higher accuracy compared with the traditional tree growth suitability evaluation, which depends on professional experience. On the other hand, certain embodiments can provide a support device (e.g., a modular sensor bar configured and adapted to receive a multiplicity of sensors with a standard interface) that can be disassembled and loaded with different commercial sensors to meet different observation requirements, that advantageously can provide a more flexible and convenient method than the traditional use of a custom sensor device for data observation. In certain embodiments, because the tree growth model can model and simulate the growth process of trees according to the biological characteristics of tree growth, long-time series simulation of the future growth process of trees can be realized by simply inputting environmental data, without deploying a large number of sensor devices to monitor the growth of trees in real-time, advantageously saving a great deal of time cost and economic cost.

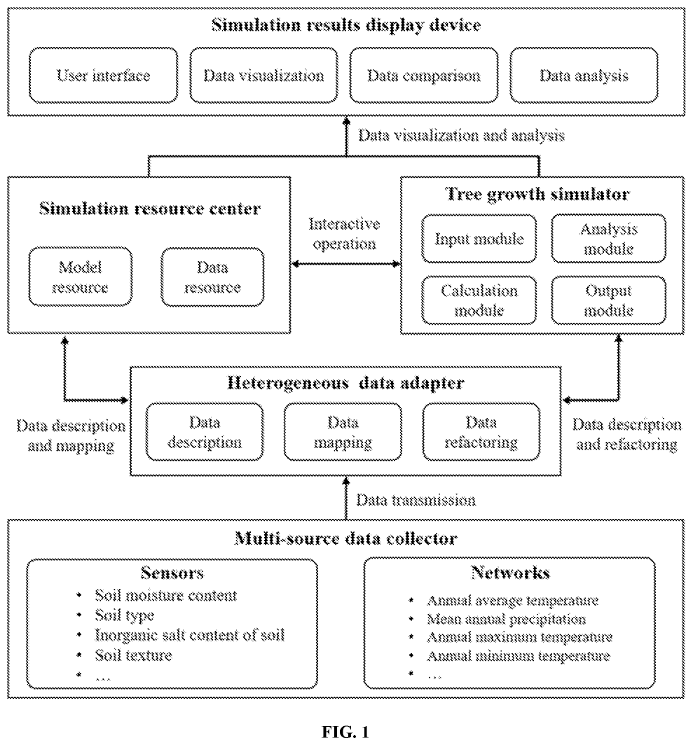

An overall framework of one embodiment of the invention is shown in FIG. 1. The instrument consists of five primary components: (1) multi-source data collector, (2) simulation resource center, (3) heterogeneous data adapter, (4) tree growth simulator and (5) simulation results display device. Through the multi-source data collector, the device can collect various data from different sources (such as soil moisture, soil inorganic salt content, annual average temperature, annual rainfall, etc.) to drive the tree growth model. Because the data from different sources are organized in different ways, heterogeneous data adapters are provided to describe and preprocess these heterogeneous data and form standardized data formats. The tree growth model and the data collected can be stored in the simulation resource center. The tree growth simulator selects a tree growth model and corresponding data from the data center to simulate the tree growth process. Finally, the results of the model are output to the display device for further decision analysis.

Referring to the design concept of combining virtual and real, embodiments can combine a tree growth model with a commercial sensor device. Traditional tree growth suitability evaluation in related art mainly relies on expert experience or deploying a large number of sensors to monitor trees in real-time to assess the future growth of trees. The former cannot take the dynamics of the urban environment into account, which often leads to inaccurate results. The latter needs to deploy a large number of sensors to observe trees for a long time with certain economic and time costs needed. The accuracy can be uncertain, which directly depends on the completeness of the monitoring scheme.

In certain embodiments, the tree growth model can be provided as a computer program for modeling and simulating various growth stages of trees. These embodiments can simulate the future growth situation of trees by introducing the tree growing model and can accurately simulate the future growing process of trees. In addition, embodiments can adopt a plug-and-play usage mode and do not need to deploy a large number of sensor-related devices and to observe trees for a long time. By designing a universal sensor access interface, the invention can access different types of sensor devices according to the data requirements of the tree growth model, thus avoiding the expensive and time-consuming practice of customizing special sensor devices due to different monitoring schemes.

Adaptation mechanism of multi-source heterogeneous data. Evaluation of tree growth suitability often requires multiple sources of data (such as soil moisture data, air temperature data, rainfall data, etc.), that can be organized in different ways. Traditional tree suitability evaluation methods in related art often combine evaluation algorithms and data processing methods, limiting the universality of evaluation methods. Embodiments provide an adaptation mechanism for multi-source heterogeneous data, wherein the adaptation mechanism can decouple the processing method of heterogeneous data from the data interface of the tree growth model. Certain embodiments of the subject invention have wider applicability and can be advantageously extended to realize the growth suitability evaluation of different types of trees.

Urban landscape tree planning is an important way to improve the urban living environment and purify urban air. Because different kinds of trees have different growth environment requirements, if certain trees are planted in an environment unsuitable for their growth, the survival rate can be reduced, thus causing certain economic losses. The evaluation of tree growth suitability is an important means to improve the survival rate of trees. At present, there are two main methods to evaluate the suitability of tree growth: (1) In the selection stage of tree species, try to choose the tree species suitable for local climate characteristics. At present, the selection of landscape trees mainly depends on planners according to the geographical location characteristics of cities and professional experience. For example, northern cities generally plant cold-resistant trees, while southern cities plant some high-temperature-resistant trees. This experience-based selection method of landscape trees can only roughly judge the matching between tree species and planting environment and cannot take into account the dynamic change of urban environments, so it can not accurately evaluate the growth suitability of trees in the planting environment. (2) After the trees are planted, the health status of the trees can be predicted by observing their growth of the trees. In this method, the growth status of trees can be monitored in real-time by adding relevant sensor devices to the planted trees, and the potential risks affecting the future growth of trees (such as insufficient soil nutrients, tree trunk growth tilt, etc.) can be artificially interfered by analyzing the monitoring data. Although this method of remedial work afterward can eliminate the potential risks that affect the future growth of landscape trees to a certain extent, it has a certain lag. It is often difficult to remedy trees that are greatly affected by the environment (for example, it is difficult to use the method of post-remedy to restore the upright growth of trees that have already grown in bending). This lag can be detrimental to the health of trees. In addition, this method needs to spend a certain amount of time and economic cost, such as deploying a large number of sensor devices to collect different types of data (such as deploying temperature sensors to collect environmental air temperature data and deploying humidity sensors to monitor air humidity), observing planted trees for a long time, and taking various remedial measures for trees affected by the environment, etc.

Embodiments of the subject invention can combine a tree growth model with a sensor device configured and adapted to obtain the data of the surrounding environment before planting trees through a plug-and-play sensor device, so as to drive the tree growth model to simulate and predict the future growth of trees and provide decision-making basis for planners to select tree species or choose sites, thereby reducing the management and maintenance cost after planting trees.

Embodiments of the subject invention can provide plug-and-play sensor devices to quickly collect the environmental data of the area to be planted, so as to drive the tree growth model to simulate and analyze the growth process of trees, and then obtain the future growth situation of trees in a specific environment. Embodiments can provide systems and methods that are easy to operate, do not need to deploy large-scale sensor equipment, and have a short implementation period. Embodiments can quickly provide decision support for planners to reduce the management and maintenance costs after planting trees as much as possible.

Compared with the current method of evaluating the suitability of tree growth by relying on prior knowledge or real-time monitoring of tree growth by sensors, embodiments of the subject invention can use the methods of model simulation, data analysis, and result prediction to better simulate and forecast the future growth of trees. This method is convenient and straightforward to operate and does not need to deploy large-scale sensor devices or observe the growth of trees for a long time. Compared with relying on prior knowledge to judge, the forecast result is more accurate, and can effectively reduce the management and maintenance costs after planting trees.

By using the urban landscape tree growth forecaster in urban landscape tree planting planning, planners do not need to deploy large-scale data acquisition devices, prior professional knowledge and long-term observation of trees. Embodiments adopt the “plug-and-play” mode of use. Different types of environmental data can be measured by attaching different types of sensors to a plug-in device of the equipment. Through the standardized processing of heterogeneous data adapters, these data can directly drive the operation of the tree growth model to quickly predict the future growth of trees.

Embodiments of the subject invention can adopt a plug-and-play mode of use. Users only need to input relevant simulation parameters in the interactive interface of the instrument and insert the support bar with the sensor into the area where trees are to be planted. The instrument can quickly obtain relevant environmental data (e.g., soil data and meteorological data) and call the corresponding tree growth model to simulate the growth process of trees. Then, the analysis module of the instrument processor analyzes the simulation results, calculates the status information of trees in each future growth stage (e.g., healthy growth of trees in the first year, sub-healthy growth of data in the second year, unhealthy growth of trees in the third year, etc.) and makes visual output, so as to provide auxiliary decision support for users to select seeds or choose sites in the landscape tree planting process.

Embodiments can provide a set of plug-and-play tree growth predictors, that can consist of five core components: (1) multi-source data collector, (2) simulation resource center, (3) heterogeneous data adapter, (4) tree growth simulator and (5) simulation results display device. Exemplary details of these core components in certain embodiments are developed further throughout this disclosure.

### Materials and Methods

The overall design framework of an urban landscape tree growth forecast instrument according to one embodiment of the subject invention is shown in FIG. 1. In this exemplary embodiment, the instrument consists of five components: (1) multi-source data collector, (2) simulation resource center, (3) heterogeneous data adapter, (4) tree growth simulator, (5) simulation results display device. Through the multi-source data collector, the device can collect various data from different sources (such as soil moisture, soil inorganic salt content, annual average temperature, annual rainfall, etc.) to drive the tree growth model. Because the data from different sources can be organized in different ways, heterogeneous data adapters are provided to describe and preprocess these heterogeneous data and form standardized data formats. The tree growth model and the data collected can be stored in the simulation resource center. Tree growth simulator selects a tree growth model and corresponding data from the data center to simulate the tree growth process. Finally, the results of the model can be output to the display device for further decision analysis.

### (1) Multi-Source Data Collector

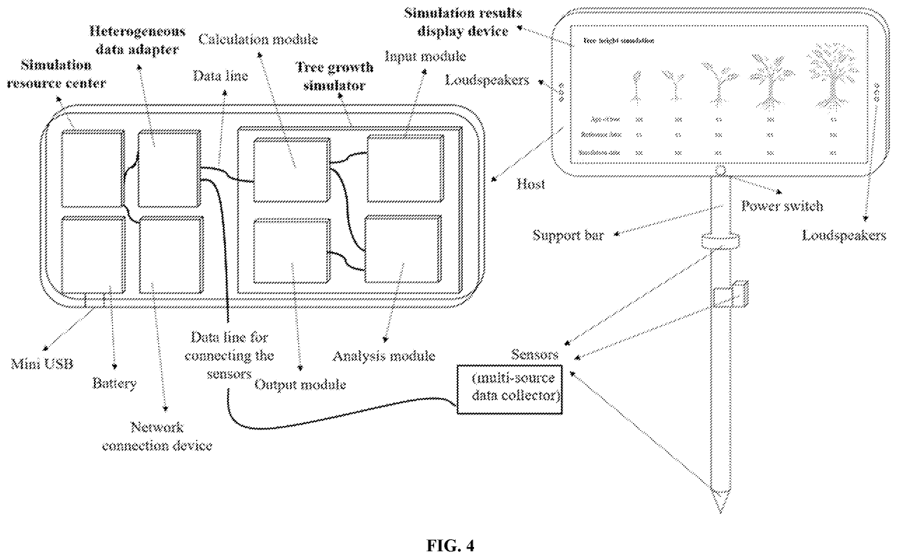

In certain embodiments, tree growth models require various types of data as input data, that can be classified according to their source: (a) Environmental data obtained using specialized sensors. For example, the soil humidity sensor can measure the relative water content data in soil, and the soil N, P, K sensors can measure the content of nitrogen, phosphorus, and potassium (NPK) in soil. (b) Web-based, online, or database-derived local, regional, or national meteorological data for the area to be planted can include annual or monthly mean precipitation data, annual or monthly mean temperature data, maximum or minimum temperature difference between day and night, sunlight exposure data, etc. Embodiments can provide a data acquisition inserted link device, as shown in FIG. 4. Exemplary embodiments of the device can be loaded with different types of sensor devices to collect different kinds of data, such as soil moisture sensors for measuring soil moisture data and network sensors for acquiring historical meteorological data in planning areas. Because these data are from different sources and organized in different ways, different types of data can advantageously be preprocessed before being used in tree growth models. To reuse these data processing methods, embodiments can provide a heterogeneous data adapter to describe the collected heterogeneous data into a uniform data format and then transmit it to the simulation resource center for storage.

### (2) Simulation Resource Center

In certain embodiments, the simulation resource center can be responsible for the resource storage and management of the whole instrument, including tree growth model resources and data resources related to model calculation, as shown in FIG. 2. The tree growth model can be a mathematical model used to simulate and predict tree growth. The model resource can be composed of several model items. Each model item represents one or some kind of tree growth model, such as Larix olgensis growth model, Korean pine growth model, and Fraxinus mandshurica growth model. Each model item can contain description information, input information, output information, etc. The data resource consists of several data items, including environmental data and model data of various landscape trees. Environmental data includes soil data and meteorological data that can be observed by environmental sensors (e.g., data directly measured from a planting site) or downloaded from a data repository (e.g., historical, local, regional, national, or general data that can be advantageously applied to a planting site.) Soil data can include information about texture, type, trace element content (such as N, P, K content) of soil. Meteorological data can contain information such as ambient temperature, humidity, and precipitation. The model data of landscape trees can include the state data of each tree species at each growth stage, such as height, stem and crown in each year of growth. Certain data and information relevant to the planting area, the trees, or the model can be advantageously considered in terms of statistical, temporal, or spatial comparisons (e.g., minimum, maximum, average, mean, range, change, variability, or variance with respect to a collection, data set, time period, or location.)

Both model and data resources need to be described standardly by data adapters to operate on a unified data view and reduce the complexity of interaction between the tree growth model and data. At the same time, it is also easy to access other tree growth models so that the instrument can support a variety of tree growth suitability evaluations.

### (3) Heterogeneous Data Adapter

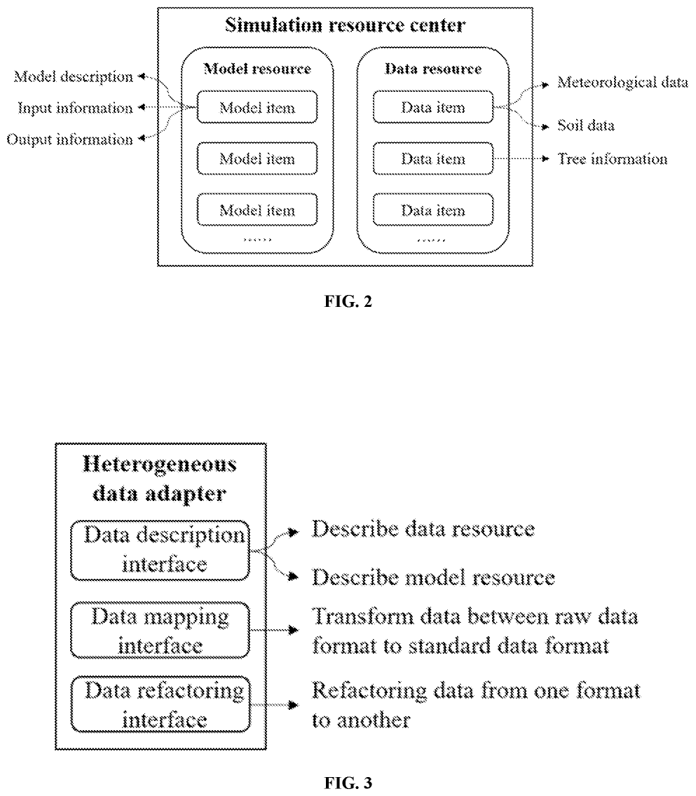

Embodiments of the heterogeneous data adapter can provide a standard data description format and establish an inter-operational link between tree growth model resources and data resources. In order to distinguish them conveniently, embodiments can refer to the data collected by the sensor as original data, and the data described by the standard data interface as standard data. As shown in FIG. 3, in certain embodiments, the data adapter can consist of or comprise three modules: (a) data description module, (b) data mapping module, and (c) data reconstruction module.

Embodiments of the data description module can provide a series of methods to describe model resources and data resources. For data resources, different types of data resources can have different organizational structures. For example, the annual mean precipitation data refers to the average annual rainfall in the area to be planted for landscape trees over a specified number of years, which can advantageously be applied to determine that the average rainfall in an area is a given value. To determine N content in soil, it can be obtained by spatial sampling in the area to be planted. In other words, each sampling point can get a value of N element content, so that the data shows that the N elements content of a given sampling point has a specified value. To shield the heterogeneity of the original data, the data description module can describe the heterogeneous data as a standard data format. That is, different types of data can be expressed in a common data view. Different models need different data resources for model resources that can need different sensor devices to measure. In order to reduce the dependence of the model on data, the data description module can describe the data interface of the model in a unified way, so that the data resources can drive the model to run as long as they are in line with the model data interface. This design method decouples the process of model simulation and data acquisition so that the sensor device can focus on data acquisition instead of paying attention to how the data is connected to the application. And tree growth models only need to focus on the simulation of the tree growth process and do not need to pay attention to the data source. Thus, if the instrument needs to be extended to other tree growth suitability evaluation types, it only needs to connect the corresponding tree growth model and related data acquisition sensor device according to the designed data interface standard.

Embodiments of the data mapping module can be mainly responsible for mapping the environmental data collected by the sensor and the standard data format, converting the original data into the standard data format. A type of data can advantageously be used to develop the corresponding data mapping methods. For example, as for the raw data collected by the soil NPK sensor, embodiments develop a mapping method to convert the original data into a standard data format. Since the mapping method follows the standard data interface design, the developed mapping method can be reused for different types of tree growth models. For example, both model A and model B need NPK data as their driving data, so the method of NPK data mapping can be developed once, such that the mapping method can meet the needs of the two models simultaneously.

Embodiments of the data reconstruction module can be mainly responsible for data conversion between standard data for specific data application requirements. After mapping the original data into the standard data format, the application of the standard data often requires some data conversion operations. For example, the sensor collects annual rainfall data in mm (e.g., data a), but the unit of input data is cm (e.g., data b). To drive the model to run correctly, the unit mm of data a needs to be converted to cm (data b) to ensure the model can run correctly. This data conversion operation can be performed by the data reconstruction method. The data reconstruction method, in a manner similar to the data mapping method, only needs to be developed once for specific application requirements and then can be reused for other same data application requirements.

### (4) Tree Growth Simulator

Embodiments of the tree growth simulator can provide a core component of the urban landscape tree growth predictor, that simulates the growth process of trees by calling the tree growth model. It mainly includes four sub-modules: input module, calculation module, analysis module and output module. The input module interacts with the user and obtains the user's input information (e.g., information such as tree species, age and condition at planting, current age and condition, and other information). In certain embodiments the calculation module drives relevant models to simulate the growth process of trees by acquiring relevant data resources (e.g., environmental data of the area to be planted) in the resource storage device. It can output the simulation results to the analysis module. The analysis module can be used to analyze the simulation results of the tree growth model. By comparing and analyzing the simulation results data (e.g., tree height, tree diameter, crown diameter and other information) of tree species at selected growth stages with the reference values in the resource storage device, the evaluation results of the growth suitability of the current landscape trees in the designated area can be obtained. For example, after one year, the growth status of trees is healthy, after 2 years, the growth status is sub-healthy, and after 3 years, the growth status is unhealthy. The output model can be responsible for calling the relevant methods in the data adapter to standardize the description and processing of these simulation results and then outputting them to the display components for visual display.

### (5) Simulation Results Display Device

Embodiments of the simulation results display device can be used for data visualization, data comparison, and data analysis of the simulation result of the urban landscape tree growth predictor and can support the interactive operation of a user, and mainly comprises three interfaces: user input interface, simulation data analysis interface, and visual simulation interface of a tree growth process. Among them, the user input interface can be used for planners to input relevant simulation parameters (e.g., tree species information of landscape trees, simulation duration, etc.). The simulation data analysis interface can be used to display the final result data after analysis of the simulation results (generally displayed in the form of charts). The tree growth process visual simulation interface can be used dynamically and visually displaying the simulation process of the model so that users can intuitively observe the whole process of the model simulation of the tree growth process.

In certain embodiments, implementing the above functional structure of the urban landscape tree growth predictor can be divided into hardware and software parts. FIG. 4 shows the hardware structure of the urban landscape tree growth forecast instrument according to one exemplary embodiment of the subject invention. In this non-limiting embodiment, the urban landscape tree growth predictor mainly comprises two types of devices: (1) a host computer, (2) a sensor device.

The host computer mainly comprises: (a) a battery that can provide mobile power for the whole urban landscape tree growth predictor; (b) a charging interface capable of charging the battery; (c) network connection device, that can provide network connection for the whole urban landscape tree growth predictor; (d) a power switch capable of turning on or off the urban landscape tree growth predictor; (e) a speaker capable of playing device sounds; (f) a resource store (e.g., in working static or dynamic memory) capable of storing related model resources and data resources; (g) a processor capable of invoking a model to simulate and analyze the tree growth process; (h) a display for interacting with the user and displaying relevant simulation and analysis results.

In this embodiment, the sensor device mainly comprises (a) a support bar capable of carrying the sensor and supporting the whole device; (b) a sensor for detecting environmental data; (c) a data connection line for transmitting data between the host computer and the sensors.

In this embodiment, the software implementation part of the urban landscape tree growth predictor can be divided into the data standardization stage and the model simulation stage.

The data standardization stage includes two parts: the standardized description of the data collected by the sensors and the standardized description of the data interface of the model. For the raw data collected by sensors, the information such as data type, data content, and data format can be described as standardized. The standardized data format can be transmitted and stored in the resource center. For the data interface of the model, the data requirements of the model (e.g., the unit dimension of the data, the content information of the data, the spatial scale information of the data, etc.) can be described in a standardized way, and the model can be encapsulated in a standardized way, so that the encapsulated model can directly accept the data in a standard format as its input data.

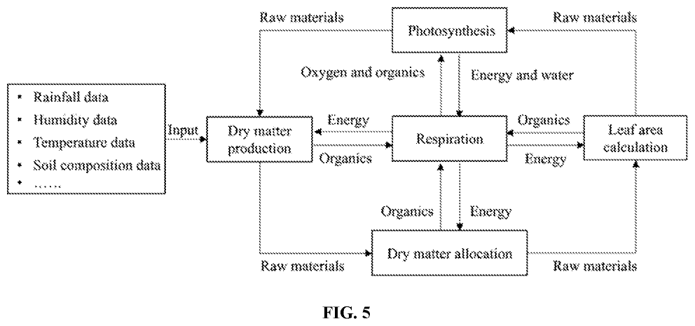

In this embodiment, the model simulation module can be divided into five sub-modules: respiration sub-module, dry matter production sub-module, dry matter distribution sub-module, leaf area calculation sub-module, and photosynthesis sub-module. The interaction relationship between each sub-module in accordance with an embodiment of the subject invention is shown in FIG. 5. Each sub-module can be connected with the model entries in the simulation resource center. After the tree species to be simulated are selected, each sub-module will automatically select the appropriate model entries in the simulation resource center to form a tree growth model to simulate the tree growth process, and then obtain information on each growth stage of the tree, such as tree crown, tree stem, and tree height.

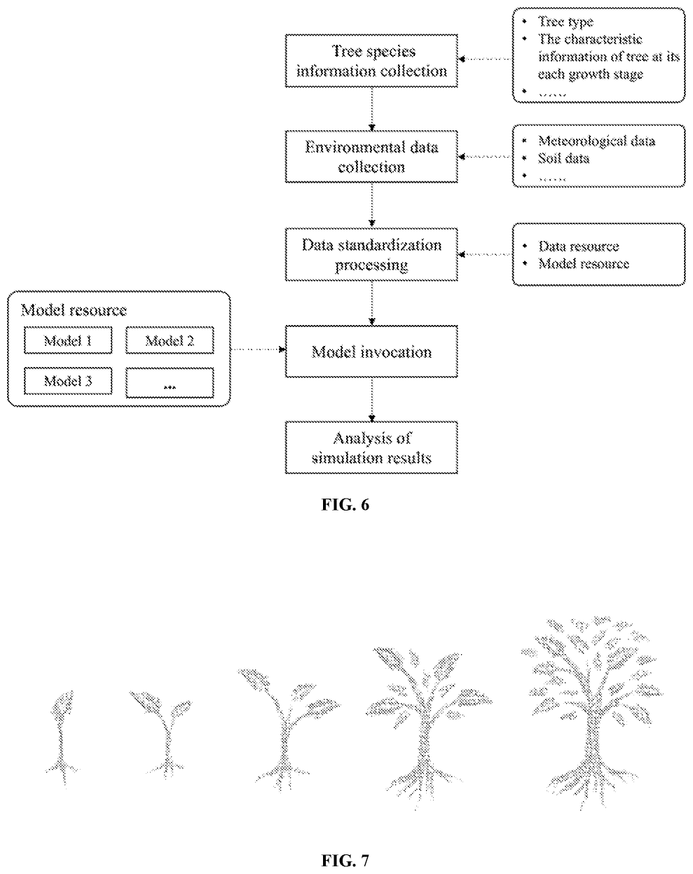

The working process of urban landscape tree growth predictor according to an exemplary and non-limiting embodiment of the subject invention is shown in FIG. 6:

### Step 1: Enter the Tree Growth Model (e.g., Tree Species Information)

In some embodiments, the tree growth model is uploaded and entered by users and stored and managed by the data center of the host computer. When the model is entered, it can be advantageous to provide relevant metadata information, such as the tree species information simulated by the model, the state information of trees in each growth stage under ideal conditions (e.g., crown radius, tree height, tree stem size, etc.), the input information and output information of the model operation, etc.

### Step 2: Obtain Environmental Data

Environmental data refers to the relevant meteorological data and soil data of the test area. In some embodiments, the meteorological data includes (average) temperature, (average) humidity, (average) rainfall and (average) sunlight information of the area, and the soil data includes soil texture, soil type and soil microelement content (such as N, P and K content). There can be two ways to obtain environmental data: field measurement by sensors, such as soil trace element content data measurement, and network or database download. Information such as monthly average temperature, monthly average humidity, monthly average rainfall, monthly average sunlight information, soil texture, and soil type data can be downloaded from relevant data download websites (e.g., the China Soil Database website, China Meteorological Data Network, etc.) and transmitted to the data repository of the host computer. In the case where the relevant environmental data are not available or are not downloaded through the network, the tree growth predictor can be used to collect enough data to meet the accuracy requirements of the tree growth model simulation.

### Step 3: Data Standardization Processing

In some embodiments, the collected original environmental data, firstly, the data type, data content, and other information are described in a standardized way to form a description document. Then, the data description document and the original data are packaged to form a standardized data packet. In the subsequent data application process, the standardized data packets can be read using the data mapping and reconstruction methods in the data adapter.

For the tree growth model, firstly, write the data interface description document of the model, and standardize the description of the data interface of the model. Then, according to the development language of the model, select the appropriate programming language to implement the data interface document so that the encapsulated model can accept the standardized data format as its input. In this way, the standardized environmental data can directly drive the operation of the model.

### Step 4: Call the Tree Growth Model

Before calling the model to evaluate the suitability of tree growth, users can configure relevant parameters. First, users can select the appropriate tree growth model from the simulation resource center of the data center according to the actual application requirements. According to the data requirements of the selected model, users can select appropriate data from the data center. According to their needs, users can configure related data processing methods, such as data reconstruction methods. Finally, this series of selection and configuration processes are connected to form a completed data workflow to drive the model to simulate the growth process of trees.

### Step 5: Analyze Simulation Data and Evaluate the Health Status of Trees

In some embodiments, the healthy state of trees refers to the growth and development state of trees, calculated from the model's simulation results. Certain embodiments are based on the simulation results of various growth stages of trees and can adopt one or more of five indexes of tree height, diameter at breast height (DBH), crown width, height-diameter ratio (ratio of tree height to DBH) and height-crown ratio (ratio of tree height to crown width) to evaluate the health status of trees. The growth and development of trees are reflected by the deviation between the simulated and reference values. The larger the deviation, the less complete the growth and development of trees. The calculation formula of the deviation value is as follows:

$$deviation value = \frac{\vert simulated value - reference value \vert}{reference value}$$

In order to distinguish the health grade of trees, embodiments can adopt the scoring strategy and record different scores according to different deviation ranges. In some embodiments, if the deviation ranges from 0% to 5%, 2 points can be scored, 1 point can be scored in the range from 5% to 10%, and no score can be scored if it exceeds 10%, as shown in Table 1.

TABLE 1
Deviation value score table

| Deviation values | Score |
|---|---|
| 0%-5% | 2 |
| 5%-10% | 1 |
| >10% | 0 |

According to the score table in Table 1, the deviation values of the five evaluation indexes of trees are calculated respectively, and the total scores of the five indexes are summarized. As shown in Table 2, the health status of trees can be divided into three grades according to the points of the total points: healthy, sub-healthy, and unhealthy.

TABLE 2
Health evaluation table

| Health status | Aggregate score |
|---|---|
| Health | 6-10 |
| Sub-healthy | 3-6 |
| Unhealthy | 0-3 |

Table 3 shows the prediction results of the future growth of trees obtained by analyzing the simulation results output by the model, which can be displayed in the simulation data analysis interface of the host computer to provide decision support for planners in accordance with an embodiment of the subject invention.

TABLE 3
Simulation and prediction results of future growth of trees

| | The first | The second | The third | The fourth | The fifth | The sixth |
|---|---|---|---|---|---|---|
| Year | year | year | year | year | year | year |
| Health status | Health | Health | Health | Sub-healthy | Sub-healthy | Unhealthy |

FIG. 7 shows the data visualization results based on the model simulation process data (tree height, tree stem, tree crown, etc.), that can be displayed in the tree growth process visualization simulation interface of the host computer display in accordance with an embodiment of the subject invention. Embodiments can provide audible, haptic, graphical, numerical, or textual representations including visualization of selected data. Representations and visualizations of selected data can be dynamic, adaptive, contextual, or coordinated.

All patents, patent applications, provisional applications, and publications referred to or cited herein are incorporated by reference in their entirety, including all figures and tables, to the extent they are not inconsistent with the explicit teachings of this specification.

Embodiments of the subject invention address the technical problem of evaluating the suitability of tree growth (e.g., predicting the growth of urban landscape trees prior to planting) by relying on prior knowledge or real-time monitoring of tree growth by sensors being expensive, time-consuming, and inaccurate. This problem is addressed by providing digital systems and methods for applying sensor and environmental data to mathematical models of tree growth to produce an improved prediction of tree growth in an accessible format based on user inputs.

Compared with the current method of evaluating the suitability of tree growth by relying on prior knowledge or real-time monitoring of tree growth by sensors, embodiments of the subject invention can use the methods of model simulation, data analysis, and result prediction to better simulate and forecast the future growth of trees. This method is convenient and straightforward to operate and does not need to deploy large-scale sensor devices or observe the growth of trees for a long time. Compared with relying on prior knowledge to judge, the forecast result is more accurate, which can effectively reduce the management and maintenance costs after planting trees.

The transitional term “comprising,” “comprises,” or “comprise” is inclusive or open-ended and does not exclude additional, unrecited elements or method steps. By contrast, the transitional phrase “consisting of” excludes any element, step, or ingredient not specified in the claim. The phrases “consisting” or “consists essentially of” indicate that the claim encompasses embodiments containing the specified materials or steps and those that do not materially affect the basic and novel characteristic(s) of the claim. Use of the term “comprising” contemplates other embodiments that “consist” or “consisting essentially of” the recited component(s).

When ranges are used herein, such as for dose ranges, combinations and sub-combinations of ranges (e.g., subranges within the disclosed range), specific embodiments therein are intended to be explicitly included. When the term “about” is used herein, in conjunction with a numerical value, it is understood that the value can be in a range of 95% of the value to 105% of the value, i.e., the value can be +/−5% of the stated value. For example, “about 1 kg” means from 0.95 kg to 1.05 kg.

The methods and processes described herein can be embodied as code and/or data. The software code and data described herein can be stored on one or more machine-readable media (e.g., computer-readable media), which can include any device or medium that can store code and/or data for use by a computer system. When a computer system and/or processor reads and executes the code and/or data stored on a computer-readable medium, the computer system and/or processor performs the methods and processes embodied as data structures and code stored within the computer-readable storage medium.

It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), and magnetic and optical storage devices (hard drives, magnetic tape, CDs, DVDs); network devices; or other media now known or later developed that are capable of storing computer-readable information/data. Computer-readable media should not be construed or interpreted to include any propagating signals. A computer-readable medium of embodiments of the subject invention can be, for example, a compact disc (CD), digital video disc (DVD), flash memory device, volatile memory, or a hard disk drive (HDD), such as an external HDD or the HDD of a computing device, though embodiments are not limited thereto. A computing device can be, for example, a laptop computer, desktop computer, server, cell phone, or tablet, though embodiments are not limited thereto.

A greater understanding of the embodiments of the subject invention and of their many advantages may be had from the following examples, given by way of illustration. The following examples are illustrative of some of the methods, applications, embodiments, and variants of the present invention. They are, of course, not to be considered as limiting the invention. Numerous changes and modifications can be made with respect to embodiments of the invention.

Embodiment 1. A system for predicting the growth of urban landscape trees in an area to be planted by a model simulation of a tree growth process, the system comprising:
a multi-source data collector comprising sensor input and network input;
a heterogeneous data adapter configured and adapted to receive data transmission from the multi-source data collector, the heterogeneous data adapter comprising a data description module, a data mapping module, and a data reconstruction module;
a simulation resource center configured and adapted to exchange data or metadata, or both, with the heterogeneous data adapter;
a tree growth simulator configured and adapted to exchange data or metadata, or both, with the heterogeneous data adapter, the tree growth simulator and the simulation resource center each, respectively, configured and adapted for interactive operation with the other; and
a simulation results display device configured and adapted to receive data comprising visualization and analysis information from the simulation resource center, the tree growth simulator, or both, and to output analysis, comparison, or visualization of the data via a user interface.

Embodiment 2. The system according to Embodiment 1, comprising:
a data acquisition inserted link device comprising:
   a housing configured and adapted to house the multi-source data collector, the heterogeneous data adapter, the simulation resource center, the tree growth simulator, and the simulation results display device;
   a sensor support bar configured and adapted to support a multiplicity of sensors and provide soil data comprising a soil moisture level and a soil mineral content to the sensor input; and
   a network connection device configured and adapted to provide local meteorological data comprising precipitation data and temperature data to the network input.

Embodiment 3. The system according to Embodiment 1, the simulation resource center comprising a tree growth model resource and a multiplicity of data resources related to model calculation.

Embodiment 4. The system according to Embodiment 3, the tree growth model resource comprising a mathematical model configured and adapted to simulate and predict tree growth.

Embodiment 5. The system according to Embodiment 4, the mathematical model comprising at least one of a Larix olgensis growth model, a Korean pine growth model, or a Fraxinus mandshurica growth model.

Embodiment 6. The system according to Embodiment 4, the data resources comprising environmental data;
the environmental data comprising soil data and meteorological data;
the soil data comprising soil texture, soil type, and soil trace element content; and
the meteorological data comprising ambient temperature, humidity, and precipitation.

Embodiment 7. The system according to Embodiment 6, the data resources further comprising a respective set of state data for each respective tree species in a multiplicity of tree species;
each respective set of state data comprising a tree height, a stem size, and a crown size, for one or more growth periods.

Embodiment 8. The system according to Embodiment 3, the heterogeneous data adapter comprising a standard data description format that defines an inter-operational link between the tree growth model resources and the multiplicity of data resources.

Embodiment 9. The system according to Embodiment 4, the heterogeneous data adapter comprising
a data description module comprising a standard data format;
a data mapping module configured and adapted to map sensor data into the standard data format; and
a data reconstruction module configured and adapted to reconstruct data from the standard data format into a respective model input format for each mathematical model.

Embodiment 10. The system according to Embodiment 9, the tree growth simulator comprising:
an input module;
a calculation module configured and adapted to drive the tree growth model resource according to the multiplicity of data resources and to produce a set of simulation results of the tree growth model;
an analysis module configured and adapted to analyze the set of simulation results of the tree growth model; and
an output module.

Embodiment 11. The system according to Embodiment 10, the calculation module comprising a model simulation module comprising five sub-modules:
a respiration sub-module;
a dry matter production sub-module;
a dry matter distribution sub-module;
a leaf area calculation sub-module; and
a photosynthesis sub-module.

Embodiment 12. The system according to Embodiment 11, wherein:
the respiration sub-module is configured and adapted to interact with each of the dry matter production sub-module, the dry matter distribution sub-module, the leaf area calculation sub-module, and the photosynthesis sub-module, respectively, by exchanging data representing organics and energy;
the respiration sub-module is further configured and adapted to interact with the photosynthesis sub-module by exchanging data representing oxygen and water; and
each sub-module of the model simulation module is connected with the model entries in the simulation resource center.

Embodiment 13. The system according to Embodiment 10, the simulation results display device comprising:
a user input interface, configured and adapted for a user to input one or more simulation parameters, the simulation parameters comprising tree species information of landscape trees, and simulation duration;
a simulation data analysis interface configured and adapted to display the final result data after analysis of the simulation results in the form of charts; and
a visual simulation interface configured and adapted to dynamically and visually display the model simulation of the tree growth process.

Embodiment 14. A method for predicting the growth of urban landscape trees in a planning area by a model simulation of a tree growth process, the method comprising the following steps:
collecting tree species information comprising tree type and growth characteristics;
standardizing the tree species information to form a model resource;
collecting environmental data comprising soil data and meteorological data;
standardizing the environmental data to form a data resource;
defining a standardized tree growth model comprising:
   a model resource input specification,
   a data resource input specification,
   a model output data specification, and
   a mathematical model configured and adapted to output a simulation result derived from inputs comprising the model resource and the data resource;
mapping the model resource into the model resource input specification;
mapping the data resource into the data resource input specification;
invoking the model to produce the simulation result; and
analyzing the simulation result.

Embodiment 15. The method according to Embodiment 14, wherein the collecting environmental data comprises the following sub-steps:
inserting a sensor support bar into an area of soil within the planning area, the sensor support bar is configured and adapted to support a multiplicity of sensors and provide the soil data;
reading the soil data from the multiplicity of sensors;
connecting a connection device to a data source, the connection device configured and adapted to provide the meteorological data; and
reading the meteorological data from the data source.

Embodiment 16. The method according to Embodiment 15, comprising:
displaying the simulation result on a simulation results display device operably connected to the sensor support bar.

Embodiment 17. The method according to Embodiment 16, wherein invoking the model to produce the simulation result occurs on a processor operably connected to both the simulation results display device and the sensor support bar.

Embodiment 18. The method according to Embodiment 17, wherein at least the following steps and sub-steps occur within the planning area:
collecting environmental data comprising soil data and meteorological data;
   inserting a sensor support bar into an area of soil within the planning area, the sensor support bar is configured and adapted to support a multiplicity of sensors and provide the soil data;
   reading the soil data from the multiplicity of sensors;
   connecting a connection device to a data source, the connection device configured and adapted to provide the meteorological data; and
   reading the meteorological data from the data source.
standardizing the environmental data to form a data resource;
mapping the data resource into the data resource input specification;
invoking the model to produce the simulation result; and
displaying the simulation result on a simulation results display device operably connected to the sensor support bar; and
analyzing the simulation result;
wherein invoking the model to produce the simulation result occurs on a processor operably connected to both the simulation results display device and the sensor support bar.

Embodiment 19. A system for predicting the growth of urban landscape trees in an area to be planted by a model simulation of a tree growth process, the system comprising:
a multi-source data collector comprising sensor input and network input;
a heterogeneous data adapter configured and adapted to receive data transmission from the multi-source data collector, the heterogeneous data adapter comprising a data description module, a data mapping module, and a data reconstruction module;
a simulation resource center configured and adapted to exchange data or metadata, or both, with the heterogeneous data adapter, the simulation resource center comprising a tree growth model resource and a multiplicity of data resources related to model calculation, the tree growth model resource comprising a mathematical model configured and adapted to simulate and predict tree growth, the mathematical model comprising at least one of a Larix olgensis growth model, a Korean pine growth model, or a Fraxinus mandshurica growth model, the data resources comprising environmental data, the environmental data comprising soil data and meteorological data, the soil data comprising soil texture, soil type, and soil trace element content, and the meteorological data comprising ambient temperature, humidity, and precipitation, the data resources further comprising a respective set of state data for each respective tree species in a multiplicity of tree species, each respective set of state data comprising a tree height, a stem size, and a crown size, for one or more growth periods;
a tree growth simulator configured and adapted to exchange data or metadata, or both, with the heterogeneous data adapter, the tree growth simulator and the simulation resource center each, respectively, configured and adapted for interactive operation with the other; and
a simulation results display device configured and adapted to receive data comprising visualization and analysis information from the simulation resource center, the tree growth simulator, or both, and to output analysis, comparison, or visualization of the data via a user interface, the simulation results display device comprising:
   a user input interface, configured and adapted for a user to input one or more simulation parameters, the simulation parameters comprising tree species information of landscape trees, and simulation duration;
   a simulation data analysis interface configured and adapted to display the final result data after analysis of the simulation results in the form of charts; and
   a visual simulation interface configured and adapted to dynamically and visually display the model simulation of the tree growth process;
a data acquisition inserted link device comprising:
   a housing configured and adapted to house the multi-source data collector, the heterogeneous data adapter, the simulation resource center, the tree growth simulator, and the simulation results display device;
   a sensor support bar configured and adapted to support a multiplicity of sensors and provide soil data comprising a soil moisture level and a soil mineral content to the sensor input; and
   a network connection device configured and adapted to provide local meteorological data comprising precipitation data and temperature data to the network input.

Embodiment 20. The system according to Embodiment 19, the heterogeneous data adapter comprising:
a data description module comprising a standard data format;
a data mapping module configured and adapted to map sensor data into the standard data format; and
a data reconstruction module configured and adapted to reconstruct data from the standard data format into a respective model input format for each mathematical model; the tree growth simulator comprising:
an input module;
a calculation module configured and adapted to drive the tree growth model resource according to the multiplicity of data resources and to produce a set of simulation results of the tree growth model;
an analysis module configured and adapted to analyze the set of simulation results of the tree growth model; and
an output module;
   the calculation module comprising a model simulation module comprising five sub-modules:
a respiration sub-module;
a dry matter production sub-module;
a dry matter distribution sub-module;
a leaf area calculation sub-module; and
a photosynthesis sub-module;
   wherein:
   the respiration sub-module is configured and adapted to interact with each of the dry matter production sub-module, the dry matter distribution sub-module, the leaf area calculation sub-module, and the photosynthesis sub-module, respectively, by exchanging data representing organics and energy;
   the respiration sub-module is further configured and adapted to interact with the photosynthesis sub-module by exchanging data representing oxygen and water; and
   each sub-module of the model simulation module is connected with the model entries in the simulation resource center.

### Example 1—Prophetic Example Evaluation of Tree Health Status, Using Sample Data

The health status of trees at each age stage can be determined using the five attributes of tree height, diameter at breast height (DBH), crown width, height-diameter ratio (ratio of tree height to DBH), and height-crown ratio (ratio of tree height to crown width).

A system for predicting the growth of urban landscape trees in an area to be planted by a model simulation of a tree growth process, in accordance with an embodiment of the subject invention, can be used to simulate planting South China Fir in Xianlin Street, Qixia District, Nanjing City. As summarized in Table 4, the tree height, DBH, and crown width after two years are 68 cm, 1.95 cm, and 6.2 cm, respectively, and the height-to-diameter ratio and height-to-crown ratio are 34.87 and 10.97, respectively. In normal conditions, the average height, DBH, and crown width of a 2-year-old South China Fir are 70 cm, 2 cm, and 6 cm, respectively, with a height-to-diameter ratio of 35 and a height-to-crown ratio of 11.67, respectively. In this example, the deviation values for each of the five indicators are as follows: 2.86 percent, 2.50 percent, 3.33 percent, 0.37 percent, and 5.99 percent, respectively. According to the index scoring strategy discussed previously, the combined score of the five indexes in this simulation is 9, indicating that the trees planted in South China Fir in Xianlin Street, Qixia District, Nanjing will be healthy in the second year.

TABLE 4
Example 1 Simulated Data

| | tree height | DBH | crown width | $\frac{tree height}{D B H}$ | $\frac{tree height}{crown width}$ |
|---|---|---|---|---|---|
| observed | 68 | 1.95 | 6.2 | 34.87 | 10.97 |
| (cm) | | | | | |
| reference | 70 | 2 | 6 | 35.00 | 11.67 |
| (cm) | | | | | |
| deviation | 2.86% | 2.50% | 3.33% | 0.37% | 5.99% |
| (percent) | | | | | |

### Example 2—Prophetic Simulation of a Tree Growth Process

A tree growth model in accordance with an embodiment of the subject invention was invoked based on the predicted area's environmental conditions and the basic information about the predicted trees in order to simulate the growth and development of trees. The environmental suitability was determined based on the simulation results.

Planting suitability evaluation can be conducted for South China Fir in Xianlin Street, Qixia District, Nanjing City, Jiangsu Province. The Chinese fir in southern China is a common street tree in the Yangtze River Basin of China. It can adapt to climatic conditions with an annual average temperature of 15-23° C., an extreme minimum temperature of −17° C., and an annual precipitation of 800-2000 mm. Xianlin Street, Qixia District, Nanjing city is a proposed location to plant South China Fir trees on both sides of the road. However, due to the influence of urbanization expansion, soil composition and meteorological conditions in Xianlin Street have changed to some extent. Therefore, it is necessary to evaluate the suitability of the South China Fir in Xianlin Street and decide whether to plant in this area according to the results. The specific steps are as follows:
1. Step 1: Environmental data collection. In this case, two types of data are required: meteorological data and soil data. The meteorological data includes the daily average temperature, daily average humidity, daily average rainfall, and daily average sunshine data for Xianlin Street. These data can be obtained from the local meteorological department and uploaded to the Xianlin Street data entry in the equipment data resource database by the user. The specific steps are as follows:
   (1) First, meteorological data types, organization formats, and contents can be standardized and described on personal computers in the form of description documents.
   (2) The downloaded weather data and description document can be packaged on a personal computer and uploaded to a data adapter.
   (3) The data items of daily mean temperature, daily mean humidity, daily mean rainfall, and daily mean sunshine in Xianlin street can be created on the display data interface of the tree growth predictor.
   (4) In the created data entry interface, a data mapping button of the data entry can establish the relationship between data and data entry.
Soil data include soil texture, soil type, and the content of soil trace elements N, P, and K, which are obtained by equipment measurement. The steps are as follows:
   (1) In the land used for planting South China Fir on both sides of Xianlin Street, sampling points can be set up every 100 meters from the beginning of the road.
   (2) Data items of soil texture, soil type and soil trace element content can be created on the display interface of the equipment by inserting the rod of the tree growth predictor into the sampling point.
   (3) The field measurement button on the data entry page can be utilized, and the tree growth predictor will automatically measure the corresponding data values and convert them into standard data, which will be stored in the resource center.
2. Step 2: Tree species information import. In this example, basic growth information of South China fir under ideal conditions needs to be imported into the equipment, including tree height, DBH, and crown width of each age group. The specific process is as follows:
   (1) Create data items of Chinese fir in south China in the display data visualization interface of the tree growth forecaster.
   (2) In the data entry interface of the South China Fir, click the data input button, and input data according to tree age in the popup data input interface. For example, [1, 2, 0.1, 0.5], the data represents tree age (years), tree height (cm), tree DBH (cm), and crown width (cm). (Alternatively, users could also write data according to the data organization rules on the PC and click the Data Import button on the device data visualization interface to import data. In a case where the tree base information already exists, this step could be unnecessary.)
3. Step 3: Gather the model's resources. In this example, the prediction model can be selected based on the following attributes: tree height, tree DBH, and crown width. (Alternatively, different attribute indexes can be simulated and predicted by different models. All models should be described in detail with input and output information and stored in the South China Fir model entry in the equipment model repository.) The specific process is as follows:
   (3) Metadata preparation. Different tree prediction models are described by unified metadata, which contains the following information:
      Tree species information
      Model input information
      Model output information
   (4) Model metadata files are packaged together with model execution files into model packages. Create the South China Fir simulation model item in the device display and upload the model package to this item. (Alternatively, this step is not required if the South China Fir model entry already exists.)
4. Step 4: Growth simulation of south China fir. Insert the plant growth predictor into the sampling points on both sides of Xianlin Street, create a simulation scheme on the device display, configure the model and data, and click “start simulation.” After the simulation, the monitor will show the growth status of China fir in the modified area in the future in the form of pictures (e.g., as shown in FIG. 7). The tree crown width and DBH in the picture are in a linear relationship with the actual simulated data. In addition, each year's data health rating (healthy, sub-healthy, and unhealthy) will be displayed below each respective picture.
5. Step 5: Repeated simulation. Repeat the fourth step at different sampling points. After the test, the equipment will evaluate the overall suitability of the area and give the final result. (Alternatively, in cases where only a single site is being measured, this step is not required.)

It should be understood that the examples and embodiments described herein are for illustrative purposes only and that various modifications or changes in light thereof will be suggested to persons skilled in the art and are to be included within the spirit and purview of this application. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

### REFERENCES

1. Ye Yiyun. Selection and Application of Roadside Tree along Main Road in Luoyuan County [J]. Forest Investigation Design,2020,40(04):41-45+48.
2. Zhao Xinya. Selection and application of street trees in urban Gardens [J]. Modern Horticulture, 2020(08):110-111.
3. Wang Shengxiang. Selection and application of street trees in urban Gardens [J]. Xiandai Horticulture, 2020,43(01):138-140.
4. Peng Buzhuo, Li Chunhua, Pu Lijie, Zhou Shenglu. A study on land suitability evaluation method in the northern margin of subtropical Qinghai Province [J]. Natural Resources,1994(02):14-21
5. Zhang Hongqi. Comprehensive evaluation of citrus land suitability supported by GIS at county level [J]. Resource Science, 1998(01):64-72.
6. Ekanayake G. K., Dayawansa N. D. K., Land suitability identification for a production forest through GIS techniques [C]//Map India Conference. 2003.
7. AbdelRahman M. A. E., Natarajan A., Hegde R., Assessment of land suitability and capability by integrating remote sensing and GIS for agriculture in Chamarajanagar district, Karnataka, India [J]. The Egyptian Journal of Remote Sensing and Space Science, 2016, 19(1): 125-141.
8. Growth prediction device for plants: WIPO (PCT), WO2001087044A1, 2001-11-22
9. Tree growth monitoring device: CN, CN202890031U, 2013-04-24
10. A real-time monitoring system and method for tree health: CN, CN111578906A, 2020-08-25

We claim:

1. A system for predicting the growth of urban landscape trees in an area to be planted by a model simulation of a tree growth process, the system comprising:
a multi-source data collector comprising sensor input and network input;
a heterogeneous data adapter configured and adapted to receive data transmission from the multi-source data collector, the heterogeneous data adapter comprising a data description module, a data mapping module, and a data reconstruction module;
a simulation resource center configured and adapted to exchange data or metadata, or both, with the heterogeneous data adapter;
a tree growth simulator configured and adapted to exchange data or metadata, or both, with the heterogeneous data adapter, the tree growth simulator and the simulation resource center each, respectively, configured and adapted for interactive operation with the other; and
a simulation results display device configured and adapted to receive data comprising visualization and analysis information from the simulation resource center, the tree growth simulator, or both, and to output analysis, comparison, or visualization of the data via a user interface.

2. The system according to claim 1, comprising:
a data acquisition inserted link device comprising:
a housing configured and adapted to house the multi-source data collector, the heterogeneous data adapter, the simulation resource center, the tree growth simulator, and the simulation results display device;
a sensor support bar configured and adapted to support a multiplicity of sensors and provide soil data comprising a soil moisture level and a soil mineral content to the sensor input; and
a network connection device configured and adapted to provide local meteorological data comprising precipitation data and temperature data to the network input.

3. The system according to claim 1, the simulation resource center comprising a tree growth model resource and a multiplicity of data resources related to model calculation.

4. The system according to claim 3, the tree growth model resource comprising a mathematical model configured and adapted to simulate and predict tree growth.

5. The system according to claim 4, the mathematical model comprising at least one of a Larix olgensis growth model, a Korean pine growth model, or a Fraxinus mandshurica growth model.

6. The system according to claim 4, the data resources comprising environmental data;
the environmental data comprising soil data and meteorological data;
the soil data comprising soil texture, soil type, and soil trace element content; and
the meteorological data comprising ambient temperature, humidity, and precipitation.

7. The system according to claim 6, the data resources further comprising a respective set of state data for each respective tree species in a multiplicity of tree species;
each respective set of state data comprising a tree height, a stem size, and a crown size, for one or more growth periods.

8. The system according to claim 3, the heterogeneous data adapter comprising a standard data description format that defines an inter-operational link between the tree growth model resources and the multiplicity of data resources.

9. The system according to claim 4, the heterogeneous data adapter comprising
a data description module comprising a standard data format;
a data mapping module configured and adapted to map sensor data into the standard data format; and
a data reconstruction module configured and adapted to reconstruct data from the standard data format into a respective model input format for each mathematical model.

10. The system according to claim 9, the tree growth simulator comprising:
an input module;
a calculation module configured and adapted to drive the tree growth model resource according to the multiplicity of data resources and to produce a set of simulation results of the tree growth model;
an analysis module configured and adapted to analyze the set of simulation results of the tree growth model; and
an output module.

11. The system according to claim 10, the calculation module comprising a model simulation module comprising five sub-modules:
a respiration sub-module;
a dry matter production sub-module;
a dry matter distribution sub-module;
a leaf area calculation sub-module; and
a photosynthesis sub-module.

12. The system according to claim 11, wherein:
the respiration sub-module is configured and adapted to interact with each of the dry matter production sub-module, the dry matter distribution sub-module, the leaf area calculation sub-module, and the photosynthesis sub-module, respectively, by exchanging data representing organics and energy;
the respiration sub-module further configured and adapted to interact with the photosynthesis sub-module by exchanging data representing oxygen and water; and
each sub-module of the model simulation module is connected with the model entries in the simulation resource center.

13. The system according to claim 10, the simulation results display device comprising:
a user input interface, configured and adapted for a user to input one or more simulation parameters, the simulation parameters comprising tree species information of landscape trees, and simulation duration;
a simulation data analysis interface configured and adapted to display the final result data after analysis of the simulation results in the form of charts; and
a visual simulation interface configured and adapted to dynamically and visually display the model simulation of the tree growth process.

14. A method for predicting the growth of urban landscape trees in a planning area by a model simulation of a tree growth process, the method comprising the following steps:
collecting tree species information comprising tree type and growth characteristics;
standardizing the tree species information to form a model resource;
collecting environmental data comprising soil data and meteorological data;
standardizing the environmental data to form a data resource;
defining a standardized tree growth model comprising:
a model resource input specification,
a data resource input specification,
a model output data specification, and
a mathematical model configured and adapted to output a simulation result derived from inputs comprising the model resource and the data resource;
mapping the model resource into the model resource input specification;
mapping the data resource into the data resource input specification;
invoking the model to produce the simulation result; and
analyzing the simulation result.

15. The method according to claim 14, wherein the collecting environmental data comprises the following sub-steps:
inserting a sensor support bar into an area of soil within the planning area, the sensor support bar is configured and adapted to support a multiplicity of sensors and provide the soil data;
reading the soil data from the multiplicity of sensors;
connecting a connection device to a data source, the connection device configured and adapted to provide the meteorological data; and
reading the meteorological data from the data source.

16. The method according to claim 15, comprising:
displaying the simulation result on a simulation results display device operably connected to the sensor support bar.

17. The method according to claim 16, wherein invoking the model to produce the simulation result occurs on a processor operably connected to both the simulation results display device and the sensor support bar.

18. The method according to claim 17, wherein at least the following steps and sub-steps occur within the planning area:
collecting environmental data comprising soil data and meteorological data;
inserting a sensor support bar into an area of soil within the planning area, the sensor support bar is configured and adapted to support a multiplicity of sensors and provide the soil data;
reading the soil data from the multiplicity of sensors;
connecting a connection device to a data source, the connection device configured and adapted to provide the meteorological data; and
reading the meteorological data from the data source;
standardizing the environmental data to form a data resource;
mapping the data resource into the data resource input specification;
invoking the model to produce the simulation result; and
displaying the simulation result on a simulation results display device operably connected to the sensor support bar; and
analyzing the simulation result;
wherein invoking the model to produce the simulation result occurs on a processor operably connected to both the simulation results display device and the sensor support bar.

19. A system for predicting the growth of urban landscape trees in an area to be planted by a model simulation of a tree growth process, the system comprising:
a multi-source data collector comprising sensor input and network input;
a heterogeneous data adapter configured and adapted to receive data transmission from the multi-source data collector, the heterogeneous data adapter comprising a data description module, a data mapping module, and a data reconstruction module;
a simulation resource center configured and adapted to exchange data or metadata, or both, with the heterogeneous data adapter, the simulation resource center comprising a tree growth model resource and a multiplicity of data resources related to model calculation, the tree growth model resource comprising a mathematical model configured and adapted to simulate and predict tree growth, the mathematical model comprising at least one of a Larix olgensis growth model, a Korean pine growth model, or a Fraxinus mandshurica growth model, the data resources comprising environmental data, the environmental data comprising soil data and meteorological data, the soil data comprising soil texture, soil type, and soil trace element content, and the meteorological data comprising ambient temperature, humidity, and precipitation, the data resources further comprising a respective set of state data for each respective tree species in a multiplicity of tree species, each respective set of state data comprising a tree height, a stem size, and a crown size, for one or more growth periods;
a tree growth simulator configured and adapted to exchange data or metadata, or both, with the heterogeneous data adapter, the tree growth simulator and the simulation resource center each, respectively, configured and adapted for interactive operation with the other; and
a simulation results display device configured and adapted to receive data comprising visualization and analysis information from the simulation resource center, the tree growth simulator, or both, and to output analysis, comparison, or visualization of the data via a user interface, the simulation results display device comprising:
a user input interface, configured and adapted for a user to input one or more simulation parameters, the simulation parameters comprising tree species information of landscape trees, and simulation duration;
a simulation data analysis interface configured and adapted to display the final result data after analysis of the simulation results in the form of charts; and
a visual simulation interface configured and adapted to dynamically and visually display the model simulation of the tree growth process;
a data acquisition inserted link device comprising:
a housing configured and adapted to house the multi-source data collector, the heterogeneous data adapter, the simulation resource center, the tree growth simulator, and the simulation results display device;
a sensor support bar configured and adapted to support a multiplicity of sensors and provide soil data comprising a soil moisture level and a soil mineral content to the sensor input; and
a network connection device configured and adapted to provide local meteorological data comprising precipitation data and temperature data to the network input.

20. The system according to claim 19, the heterogeneous data adapter comprising:
a data description module comprising a standard data format;
a data mapping module is configured and adapted to map sensor data into the standard data format; and
a data reconstruction module configured and adapted to reconstruct data from the standard data format into a respective model input format for each mathematical model; the tree growth simulator comprising:
an input module;
a calculation module configured and adapted to drive the tree growth model resource according to the multiplicity of data resources and to produce a set of simulation results of the tree growth model;
an analysis module configured and adapted to analyze the set of simulation results of the tree growth model; and
an output module;
the calculation module comprising a model simulation module comprising five sub-modules:
a respiration sub-module;
a dry matter production sub-module;
a dry matter distribution sub-module;
a leaf area calculation sub-module; and
a photosynthesis sub-module;
wherein:
the respiration sub-module is configured and adapted to interact with each of the dry matter production sub-module, the dry matter distribution sub-module, the leaf area calculation sub-module, and the photosynthesis sub-module, respectively, by exchanging data representing organics and energy;
the respiration sub-module further configured and adapted to interact with the photosynthesis sub-module by exchanging data representing oxygen and water; and
each sub-module of the model simulation module is connected with the model entries in the simulation resource center.
